(19) United States
(12) Patent Application Publication
(10) Pub. No.: US 2017/0069393 A1
(43) Pub. Date: Mar. 9, 2017

(54) MEMORY DEVICE

(71) Applicant: Kabushiki Kaisha Toshiba, Minato-ku (JP)

(72) Inventors: Koki UENO, Yokohama (JP); Yasuhiro SHllNO, Fujisawa (JP); Asuka KANEDA, Yokohama (JP); Aki KO, Kamakura (JP)

(73) Assignee: Kabushiki Kaisha Toshiba, Minato-ku (JP)

(21) Appl. No.: 14/937,070

(22) Filed: Nov. 10, 2015

Related U.S. Application Data
(60) Provisional application No. 62/216,141, filed on Sep. 9, 2015.

(51) Int. Cl. G11C 16/26; G11C 16/08; G11C 16/10

(52) U.S. Cl. CPC G11C 16/26; G11C 16/10; G11C 16/08

(57) ABSTRACT

A memory device according to one embodiment includes cell transistors; and a controller which is configured to write data in a first page and a second page and read data from the first and second pages, and when the controller writes data in the second page of the cell transistors with data written in the first page, reads data from the first page, uses a first value or a second value for a first parameter based on the read data, and uses a third value or a fourth value for a second parameter based on the read data.

### CROSS-REFERENCE TO RELATED APPLICATIONS

This application claims the benefit of U.S. Provisional Application No. 62/216,141, filed Sep. 9, 2015, the entire contents of which are incorporated herein by reference.

### FIELD

Embodiments relates to a memory device.

### BACKGROUND

Memory devices which can store two or more bits of data in one memory cell are known.

### BRIEF DESCRIPTION OF THE DRAWINGS

FIG. 1 illustrates functional blocks of a memory device of a first embodiment;

FIG. 2 illustrates some components and connections of a memory cell array of the memory device of the first embodiment;

FIG. 3 illustrates a cross sectional view of the memory cell array of the memory device of the first embodiment;

FIG. 4 illustrates components and connections of a sense amplifier circuit of the memory device of the first embodiment;

FIG. 5 illustrates an example of the relationship between data stored in cell transistors of the memory device of the first embodiment and threshold voltages;

FIG. 6 illustrates voltages applied to a selected word line during a write of the memory device of the first embodiment along time;

FIG. 7 illustrates an example of a threshold voltage distribution based on write loop numbers of the memory device of the first embodiment;

FIG. 8 illustrates an operation to detect the loop number in which a particular condition is fulfilled in the memory device of the first embodiment;

FIG. 9 illustrates assignment of the use of units in the memory device of the first embodiment;

FIG. 10 illustrates a table of parameters and adjustment values in the memory device of the first embodiment;

FIG. 11 illustrates potentials applied to components in a selected block during a write in the memory device of the first embodiment;

FIG. 12 illustrates potentials applied to components in the selected block during a verification in the memory device of the first embodiment;

FIG. 13 illustrates potentials of some nodes during the verification of the memory device of the first embodiment along time;

FIG. 14 illustrates potentials applied to components in the selected block during a write of the memory device of the first embodiment;

FIG. 15 illustrates shifts of distributions of the threshold voltages due to a repetition of writes and erases;

FIG. 16 illustrates a table of parameters and adjustment values in a memory device of a second embodiment; and

FIG. 17 illustrates potentials applied to components in a selected block during a verification in the memory device of the second embodiment.

### DETAILED DESCRIPTION

A memory device according to one embodiment includes cell transistors; and a controller which is configured to write data in a first page and a second page and read data from the first and second pages, and when the controller writes data in the second page of the cell transistors with data written in the first page, reads data from the first page, uses a first value or a second value for a first parameter based on the read data, and uses a third value or a fourth value for a second parameter based on the read data.

Embodiments will now be described with reference to the figures. In the following description, components with substantially the same functionalities and configurations will be referred to with the same reference numeral, and repeated description is omitted. All descriptions for a particular embodiment are also applicable as descriptions for another embodiment unless they are indicatively or obviously inapplicable. An embodiment only illustrates devices and methods for materializing the technical idea of the embodiment, and the technical idea of the embodiments do not specify the quality of the material, form, structure, arrangement of components, etc. to the following. Each functional block can be implemented as hardware, computer software, or combination of the both. It is not necessary that functional blocks are distinguished as in the following examples. For example, some of the functions may be implemented by functional blocks different from those illustrated below.

### First Embodiment

### Configuration, or Structure

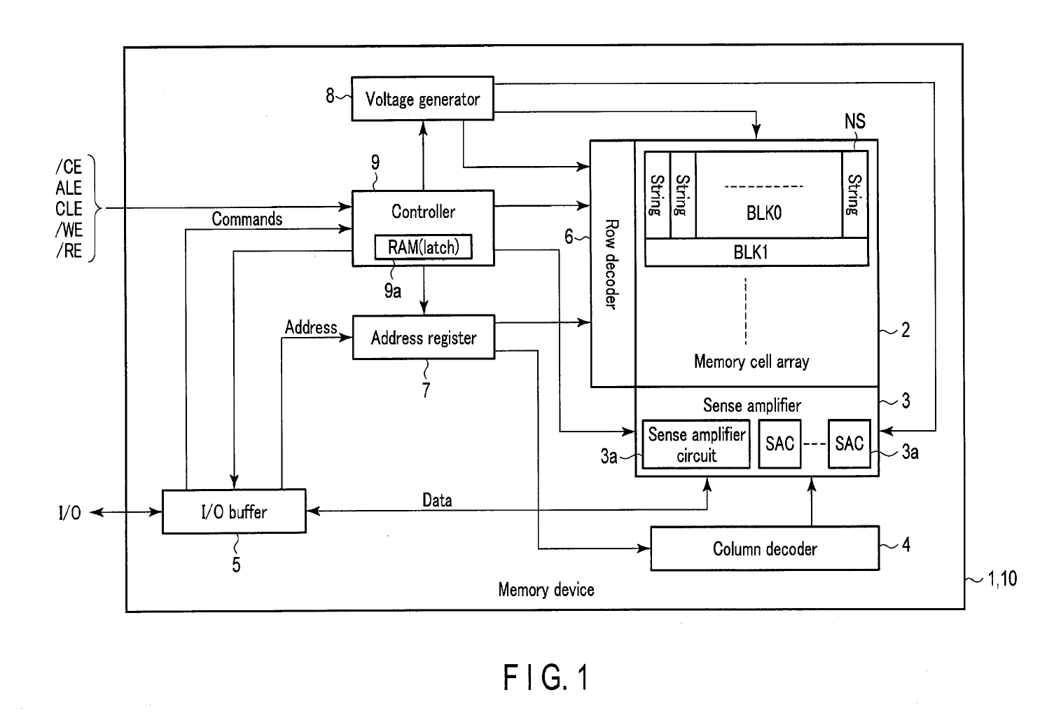

FIG. 1 illustrates functional blocks of a semiconductor memory device according to a first embodiment. As illustrated in FIG. 1, the memory device 1 includes a memory cell array 2, a sense amplifier 3, a column decoder 4, an IO buffer 5, a row decoder 6, an address register 7, a voltage generator 8, and a controller 9. The memory cell array 2 includes plural memory blocks BLK (BLK0, BLK1, . . . ). Each block BLK includes plural strings NS.

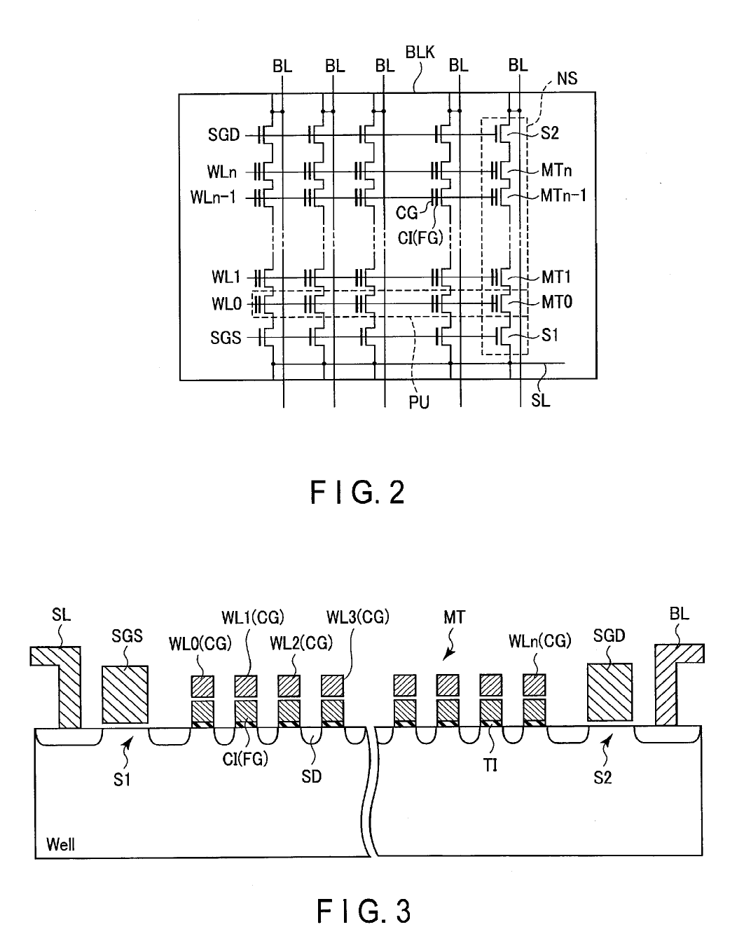

Each block BLK has components and connections illustrated in FIG. 2, and has the structure illustrated in FIG. 3. FIG. 3 illustrates a cross sectional view of the memory cell array 2. As illustrated in FIGS. 2 and 3, each string NS includes n+1 cell transistors MT (MT0 to MTn) and select gate transistors S1 and S2, which are coupled in series. n is a natural number. Each cell transistor MT includes a tunnel insulator TI on a well in a semiconductor substrate (not shown), a charge storage layer CI on the tunnel insulator TI, an inter-gate insulator (not shown) on the charge storage layer CI, a control gate electrode CG (WL) on the inter-gate insulator, and source or drain areas SD. The charge storage layer CI is, for example, a floating gate electrode (FG), or may be an insulator. Each cell transistor MT has a threshold voltage that varies according to the number of electrons included in the charge storage layer CI.

The transistor S1 is coupled between a source line SL and the cell transistor MT0, and the transistor S2 is coupled between one bit line BL and the cell transistor MTn. Data in the cell transistors MT in the block BLK are erased together.

Respective control gate electrodes CG of respective cell transistors MTX (X being zero or a natural number equal to or lower than n) of the strings NS are coupled to a word line WLX in common. The cell transistors MT coupled to the same word line WL make a unit PU. The cell transistors MT of one unit PU have data written and read together. The memory space of one unit PU includes one or more pages.

Respective gates of respective transistors S1 of the strings NS are coupled to a select gate line SGS. Respective gates of respective transistors S2 of the strings NS are coupled to a select gate line SGD.

Referring back to FIG. 1, the voltage generator 8 generates various voltages from the power voltage in accordance with instructions of the controller 9.

The IO buffer 5 temporarily stores signals received from the outside of the memory device 1 on an IO bus. The signals flowing through the IO bus include write data, commands, an address signal, and read data. The address signal is stored in the address register 7. The address signal includes a row address and a column address.

The row decoder 6 receives various voltages from the voltage generator 8. The row decoder 6 applies the received voltages to one of the word lines WL selected based on the row address (selected word line) and unselected word lines WL in one of the blocks BLK specified by the row address (selected block). The column decoder 4 selects one or more of the columns based on the column address. The columns are associated with the bit lines BL.

The sense amplifier 3 includes plural sense amplifier circuits 3a. Each sense amplifier circuit 3a is coupled to one bit line BL. The sense amplifier 3 determines the states of the cell transistors MT through the bit lines BL, and reads data stored in the cell transistors MT. The sense amplifier 3 receives voltages of various values from the voltage generator 8, and applies the received voltages to the bit lines BL during writes based on the column address, write data and/or the states of the bit lines BL.

The controller 9 receives various control signals from the outside of the memory device 1, and receives the commands from the IO buffer 5. The control signals include a chip enable /CE, address latch enable ALE, command latch enable CLE, write enable /WE, and read enable /RE. The controller 9 controls the components in the memory device 1, such as the voltage generator 8, the row decoder 6, and the sense amplifier 3, based on the control signals and commands. The controller 9 includes a random access memory (RAM) or data latch 9a, and stores various data in the RAM 9a.

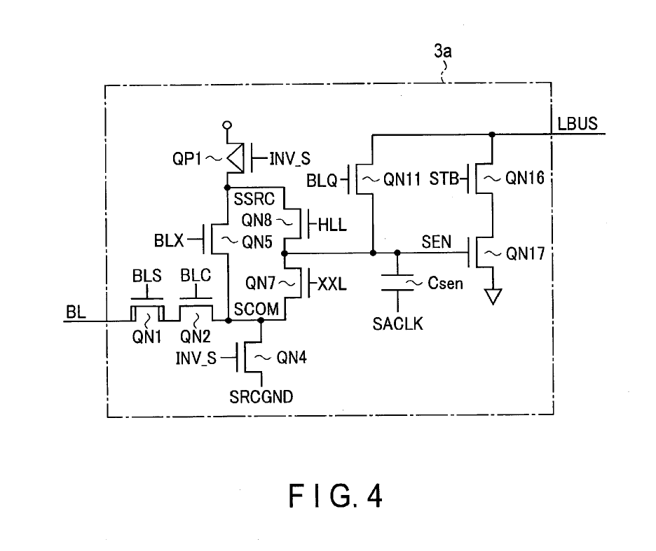

The sense amplifier circuit 3a will now be described with reference to FIG. 4. As illustrated in FIG. 4, the bit line BL is coupled to a node SCOM through serially coupled n-type MOSFETs QN1 and QN2. The transistors QN1 and QN2 receive at their gates signals BLS and BLC from the controller 9, respectively. The node SCOM is coupled to a node SRCGND through an n-type MOSFET QN4. The transistor QN4 receives at its gate a signal INV_S from the controller 9. The node SRCGND has the ground potential VSS.

The node SCOM is also coupled to a power potential node (or, node of the power potential VDD) through an n-type MOSFET QN5 and a p-type MOSFET QP1, which are coupled in series. The transistors QN5 and QP1 receive at their gates signals BLX and INV_S from the controller 9, respectively. The node SCOM is further coupled to the node SEN through an n-type MOSFET QN7. The transistor QN7 receives a signal XXL from the controller 9 at the gate.

The node SEN is coupled through an n-type MOSFET QN8 to the node SSRC between the transistors QN5 and QP1. The transistor QN8 receives a signal HLL from the controller 9 at the gate. The node SEN also receives a signal SACLK through a capacitor Csen. The node SEN is further coupled to a node LBUS through an n-type MOSFET QN11. The transistor QN11 receives a signal BLQ from the controller 9 at the gate.

The node LBUS is coupled to a data latch (not shown). The node LBUS is also grounded through n-type MOSFETs QN16 and QN17, which are coupled in series. The transistor QN16 receives a signal STB from the controller 9 at the gate. The transistor QN17 is coupled to the node SEN at the gate.

(Operation)

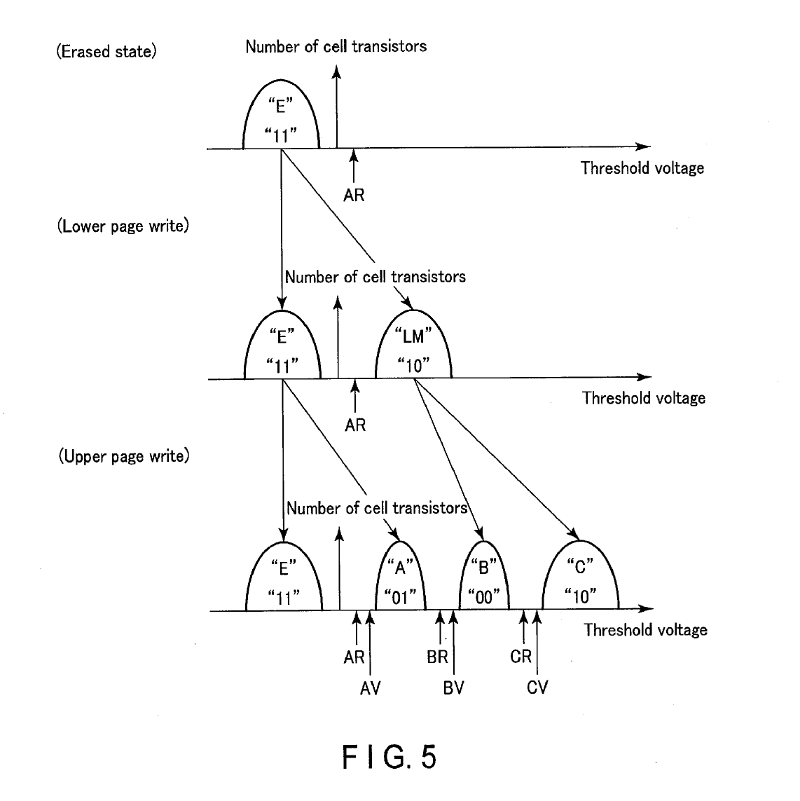

The memory device 1 can store data of one or more bits in one cell transistor MT. First, this storing of multiple levels per cell will be described with reference to FIG. 5.

FIG. 5 illustrates an example of the relationship between data stored in the cell transistors MT and threshold voltages. FIG. 5 and the following description are based on an example of storing of two-bit data per cell transistor MT. In the storing of two bits per cell transistor MT, each cell transistor MT may have one of four threshold voltages. The four threshold voltages are associated with “11” data, “01” data, “10” data, and “00” data, for example. The set of the upper bits stored in respective cell transistors MT of each unit PU is referred to as an upper page, and the set of the lower bits is referred to as a lower page. The upper page and the lower page are assigned different physical addresses.

Even cell transistors MT which store the same two-bit data may have different threshold voltages, due to various factors. For this reason, the threshold voltages have distributions. The distributions are referred to as E, A, B, and C-levels, for example. The threshold voltages in the A-level are higher than the threshold voltages in the E-level. The threshold voltages in the B-level are higher than the threshold voltages in the A-level. The threshold voltages in the C-level are higher than the threshold voltages in the B-level. The cell transistors MT with threshold voltages of the E-levels are in an erased state, and have no electrons injected.

For determination of data stored in read-target cell transistors MT, the levels to which the threshold voltages of those cell transistors MT belong are determined. For the determination of the levels, read voltages AR, BR, and CR are used. Whether a read-target cell transistor MT has a threshold voltage higher or lower a particular read voltage is used to determine the threshold voltage of that cell transistor MT. The read voltage AR is located between the E-level and A-level. The read voltage BR is located between the A-level and B-level. The read voltage CR is located between the B-level and C-level. Hereinafter, a voltage of a particular value applied to a read-target cell transistor MT for determining the level, including the voltages AR, BR and CR, may be referred to as a read voltage Vcgr.

For a write of two-bit data, cell transistors MT first have data written in the lower page written, and then data written in the upper page. The write in the lower page includes maintaining cell transistors MT in the state of the E-level or transferring them to a state referred to as an LM-level. The LM-level corresponds to the state where “0” data has been written in the lower page, and is treated as a state of storing, for example, “10” data. The threshold voltages in the LM-level are higher than the read voltage AR. A read from the cell transistors MT with data written only in the lower page thereof is based on whether each of the cell transistors MT has the threshold voltage larger than the read voltage AR.

The write in the upper page of cell transistors MT with data written in the lower page thereof includes maintaining cell transistors MT of the E-level at the E-level or transferring them to the A-level, and transferring those of the LM-level to the B or C-level.

Verification voltages AR, BR, and CR are used during a write to the cell transistors MT, and are used for determination on whether the write into the A, B, and C-levels have completed, respectively. Hereinafter, a voltage of a particular value applied to a write-target cell transistor MT for verification, including the voltages AV, BV, and CV, may be referred to as a verification voltage VVR.

The above combinations of levels and two-bit data are an example. With other combinations, other sets of read voltages are used for the read of the upper page and the lower page. The same holds true for the verification voltage.

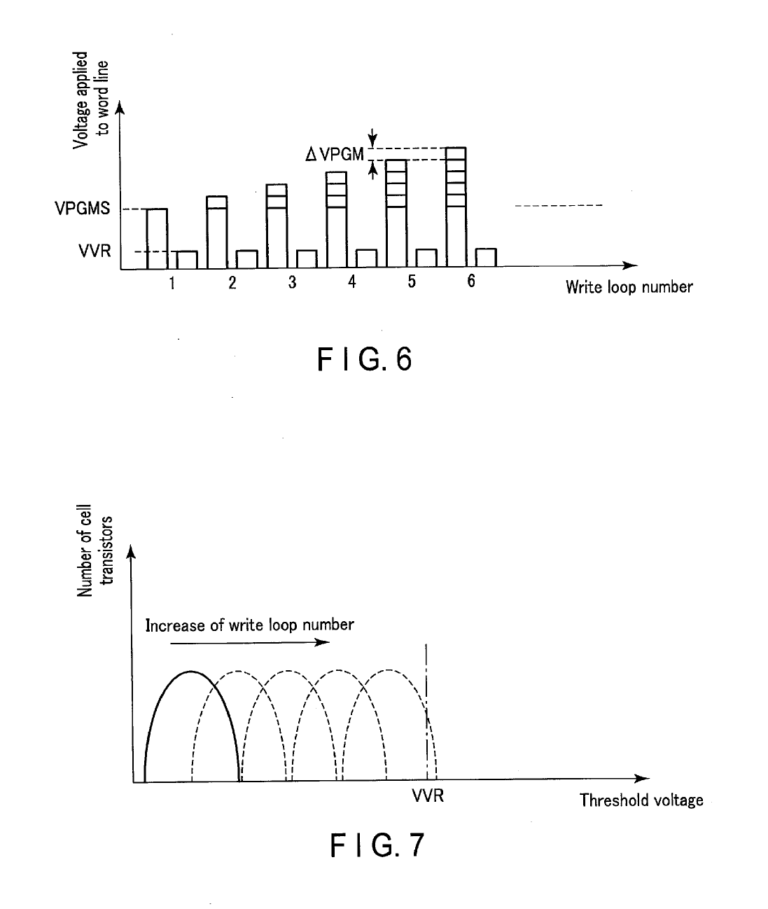

A description will now be given of data writes in the memory device 1 with reference to FIGS. 6 to 15. The write to an upper page and the write to a lower page are the same in some respects, and different in some respects. Hereinafter, points common to the writes to the lower page and the upper page are described with reference to FIGS. 6 and 7. Both the writes to the lower page and the upper page include plural sets of a program and a verification. The program refers to raising the threshold voltages of write-target cell transistors MT, and includes application of program voltages to the word lines WL. The verification refers to a verification of whether a program has been correctly performed. The verification is the same as a read of data with a difference in the voltage applied to the target word line WL, and includes a read accompanied by application of the verification voltage VVR to the word line WL.

As illustrated in FIG. 6, the controller 9 controls the voltage generator 8 and the sense amplifier 3 to repeat the loop of application of a program voltage to the control gate electrode CG of the write-target cell transistor MT (selected word line WL) and a verification of those cell transistors MT. The loop may be hereinafter referred to as a write loop. The program voltage has an increased value in every loop, and a program voltage in a particular loop is higher than the program voltage in the last loop by an increment (difference) ΔVPGM. The increment ΔVPGM is a difference between the program voltage applied in a particular write loop, and the program voltage applied by the last loop, and has a particular value.

As illustrated in FIG. 7, a distribution of threshold voltages shifts in the positive direction in every execution of the write loop. The controller 9 determines whether the threshold voltages of a particular number of cell transistors MT in a write-target unit PU exceeds the verification voltage VVR which is based on the data to be written in every execution of the write loop. If not exceeded, the controller 9 performs the next write loop, and if exceeded, the controller 9 determines that the verification is a pass. When the verification passes, the write ends for a case of the lower page write. For a case of the upper page write, when the verification for the write into the A-level passes, the write into the C-level starts, and in turn when the verification of the write into the C-level passes, the write to the upper page ends.

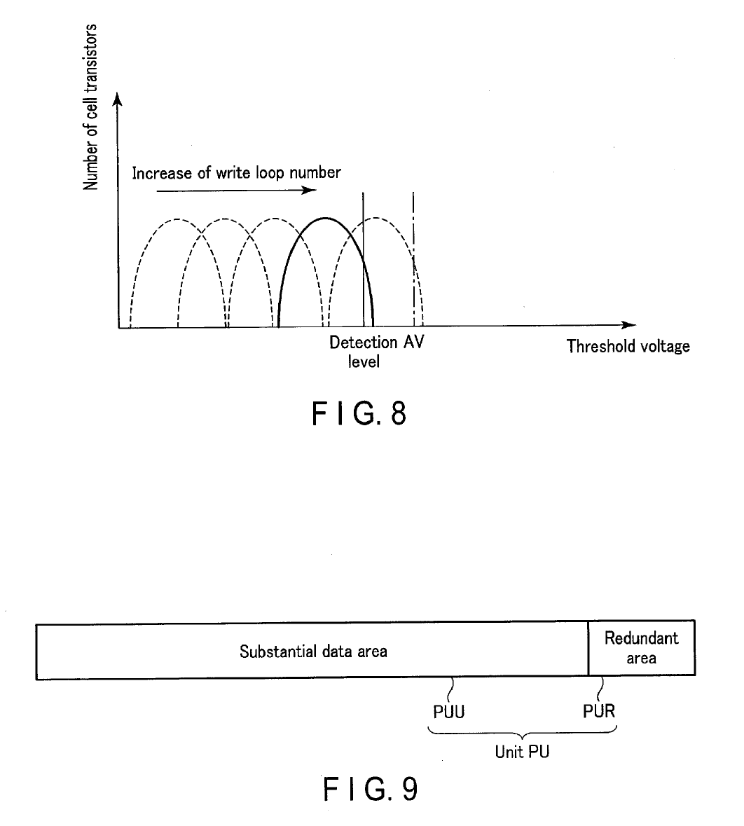

The write into the lower page will be described with reference to FIG. 8. The controller 9 searches for a loop number in which a distribution of threshold voltages comes to fulfill a particular condition during the write of the lower page. The condition is, for example, that the threshold voltages of cell transistors MT of a particular number or ratio in the write-target unit PU exceed a particular voltage (to be referred as a detection level hereinafter). The detection level is lower than the verification voltage AV for the lower page write. The controller 9 writes in the cell transistors MT the loop number in which the condition comes to be fulfilled (to be referred to as a detection loop number hereinafter). As illustrated in FIG. 9, for example, the controller 9 writes the detection loop number in the lower page of cell transistors MT of a redundant area PUD in the write-target unit PU by programs in loops after the detection loop number and before the verification passes. The redundant area PUR is a section other than a substantial (or, user) data area PUU in a unit PU. The device outside of the memory device 1 can write data in the substantial data area PUU. The controller 9 writes management data including the detection loop number in the redundant area PUR.

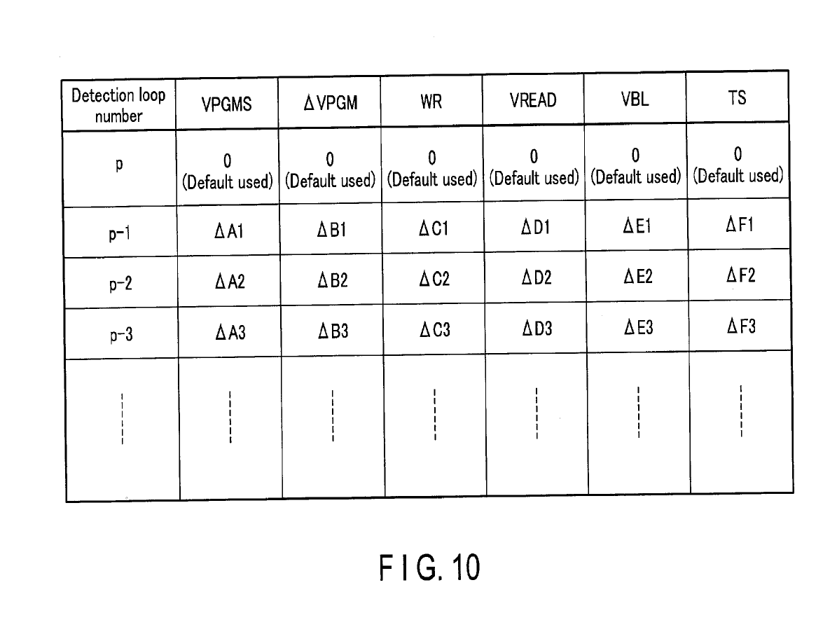

The write to the upper page will now be described with reference to FIGS. 10 to 15. When the memory device 1 receives a command which instructs a write to a particular upper page, the controller 9 starts the write to the upper page specified by the command. First, the controller 9 controls components, such as the voltage generator 8, the row decoder 6, and the sense amplifier 3, to read the detection loop number from the lower page of the unit PU which will store the data in the write-target upper page. The controller 9 writes the data in the upper page based on the read detection loop number. Specifically, the controller 9 adjusts values of one or more of parameters for controlling the write based on the detection loop number. More specifically, the default value is prepared for a parameter for write, and the controller 9 adds a value according to the detection loop number (adjustment value) to the default value to use the resultant value.

Among the parameters used in writes, parameters to be adjusted include one, some, or all of a start program potential VPGMS and the increment ΔVPGM in the programs, and the verification potential VVR and a bias potential VREAD, a precharge potential VBL, and a sense time TS in the verifications. The values of additional parameters may be adjusted. The potential VPGMS refers to a program potential of a particular value used in the first write loop. The bias potential VREAD refers to a potential of a particular value applied to word lines WL other than the selected word line WL coupled to the read-target unit PU, i.e., unselected word lines. The precharge potential VBL refers to a potential of a particular value applied to the bit lines BL during the read and verification. The sense time is a time of a particular length until the state of the sense amplifier 3 becomes the state in which it can determine data after the state changes based on the read-target cell transistors MT. They are described in detail in the following.

The controller 9 stores a table illustrated in, for example, FIG. 10, in the RAM9a while the memory device 1 is being supplied with power. The table is stored, for example, in the cell transistors MT, and read to the RAM9a when power starts to be supplied to the memory device 1. As illustrated in FIG. 10, for each value of the detection loop number, adjustment values for respective parameters are determined. The adjustment values are determined in advance by an experiment, simulation, etc., for example. The adjustment values may be dynamically changed.

The first row shows the values for respective parameters for the detection loop number of p. p is a natural number. The detection loop number p indicates the loop number in which the cell transistors MT immediately after a write fulfill the condition. For the detection loop number p, default values are used for all the parameters.

The potential VPGMS is adjusted to have a larger value for a case of a smaller detection loop number. To this end, adjustment values ΔA1, ΔA2, . . . are respectively prepared for the potential VPGMS for the detection loop numbers in descending order, and all the adjustment values ΔA (ΔA1, ΔA2, . . . ) have positive values. Differences between two respective values ΔA in adjacent two rows may be the same or different in each pair. For the other parameters to be described below, the differences of two values may be the same or different in some pairs of values.

The increment ΔVPGM is adjusted to have a smaller value for a case of a smaller detection loop number. To this end, adjustment values ΔB1, ΔB2, . . . are respectively prepared for the increment ΔVPGM for the detection loop numbers in descending order, and all the adjustment values ΔB (ΔB1, ΔB2, . . . ) have negative values.

The verification potential VVR is adjusted to have a larger value for a case of a smaller detection loop number. To this end, adjustment values ΔC1, ΔC2, . . . are respectively prepared for the verification potential VVR for the detection loop numbers in descending order, and all the adjustment values ΔC (ΔC1, ΔC2, . . . ) have positive values.

The potential VREAD is adjusted to have a larger value for a case of a smaller detection loop number. To this end, adjustment values ΔD1, ΔD2, . . . are respectively prepared for the potential VREAD for the detection loop numbers in descending order, and all the adjustment values ΔD (ΔD1, ΔD2, . . . ) have positive values.

The precharge potential VBL is adjusted to have a larger value for a case of a smaller detection loop number. To this end, adjustment values ΔE1, ΔE2, . . . are respectively prepared for the precharge potential VBL for the detection loop numbers in descending order, and all the adjustment values ΔE (ΔE1, ΔE2, . . . ) have positive values.

The sense time TS is adjusted to have a larger value for a case of a smaller detection loop number. To this end, adjustment values ΔF1, ΔF2, . . . are respectively prepared for the sense time TS for the detection loop numbers in descending order, and all the adjustment values ΔF (ΔF1, ΔF2, . . . ) have positive values.

The controller 9 uses the read detection loop number to perform the first write loop to execute a write to the upper page as described in the following. First, the controller 9 uses the read detection loop number to learn the adjustment value for the potential VPGMS for that detection loop number. The controller 9 controls components, such as the voltage generator 8, the row decoder 6, and the sense amplifier 3, to use the default program potential VPGM or the program potential VPGM adjusted by addition of the adjustment value to apply a voltage for the write to associated components. The details are as follows.

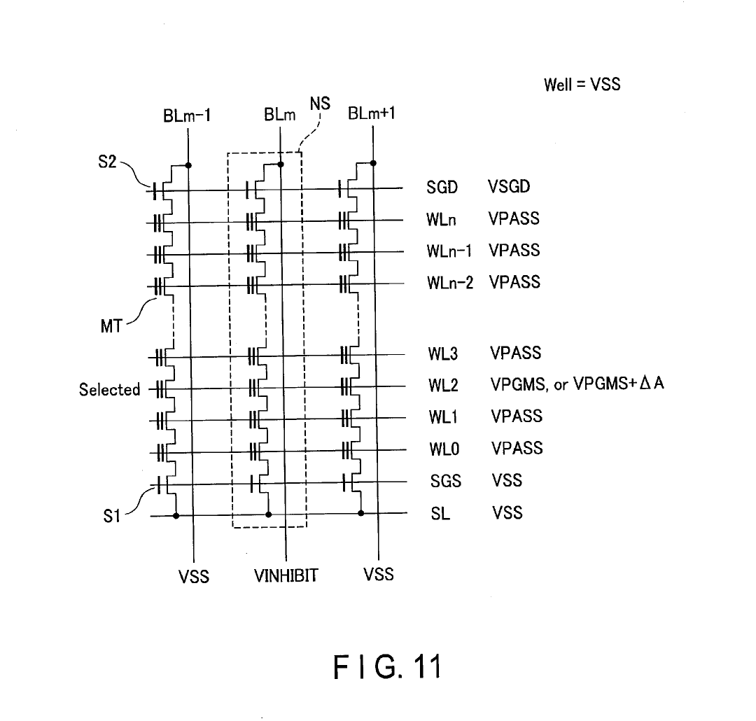

FIG. 11 illustrates potentials applied to components in the block BLK which includes the write-target unit PU (selected block) during a write in the memory device 1. As illustrated in FIG. 11, the controller 9 applies a potential VSGD to the select gate line SGD. The potential VSGD has a magnitude which turns on the select gate transistor S2. The controller 9 maintains the potentials of the select gate line SGS and the well at the potential VSS (=0V). The controller 9 maintains the potentials of respective bit lines BL coupled to NAND strings NS which include cell transistors MT which will have “0” data written in respective upper bits at the potential VSS to maintain them in a so-called program state. In contrast, the controller 9 makes the potentials of respective bit lines BL coupled to strings NS which include cell transistors MT which will have “1” data written in respective upper bits at, for example, a potential VINHIBIT to maintain them in a so-called inhibit state. The potential VINHIBIT is higher than the potential VSS. The controller 9 applies a path potential VPASS to the unselected word lines WL. The controller 9 applies the default program potential VPGMS or the adjusted program potential VPGMS+ΔA. Such application of voltages applies a program voltage to the cell transistors MT which is coupled to the selected word line WL and will have “0” data written in the unit PU.

The memory device 1 then performs a verification in the first write loop. First, the controller 9 uses the read detection loop number to learn the respective adjustment values for the precharge potential VBL, the bias potential VREAD, the verification potential VVR, and the sense time ST for that detection loop number. The controller 9 controls components, such as the voltage generator 8, the row decoder 6, and the sense amplifier 3, and uses the default or adjusted potentials VBL, VREAD, VVR, and sense time ST to perform the verification. The controller 9 performs the verification to cell transistors MT which should have threshold voltages of the C-level by the write or cell transistors MT which should have threshold voltages of the A-level by the write. Either verification may be performed first. For example, the controller 9 performs the A-level verification first. The details of the verification are as follows.

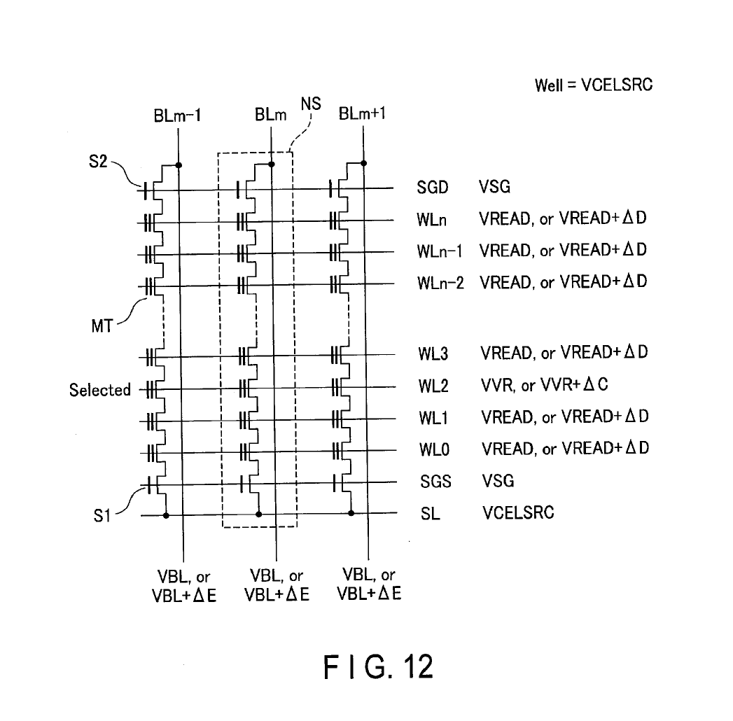

FIG. 12 illustrates potentials applied to component in the selected block BLK during verification by the memory device 1. As illustrated in FIG. 12, the controller 9 applies a potential VSG to the select gate lines SGD and SGS. The potential VSG has a magnitude to turn on the select gate transistors S1 and S2. The controller 9 applies the default precharge potential VBL or the adjusted precharge potential VBL+ΔE to all the bit lines BL. The controller 9 applies to the source line SL a potential VCELSRC of a magnitude smaller than the potential VBL. The controller 9 applies the default bias potential VREAD or the adjusted bias potential VREAD+ΔD to the unselected word lines WL.

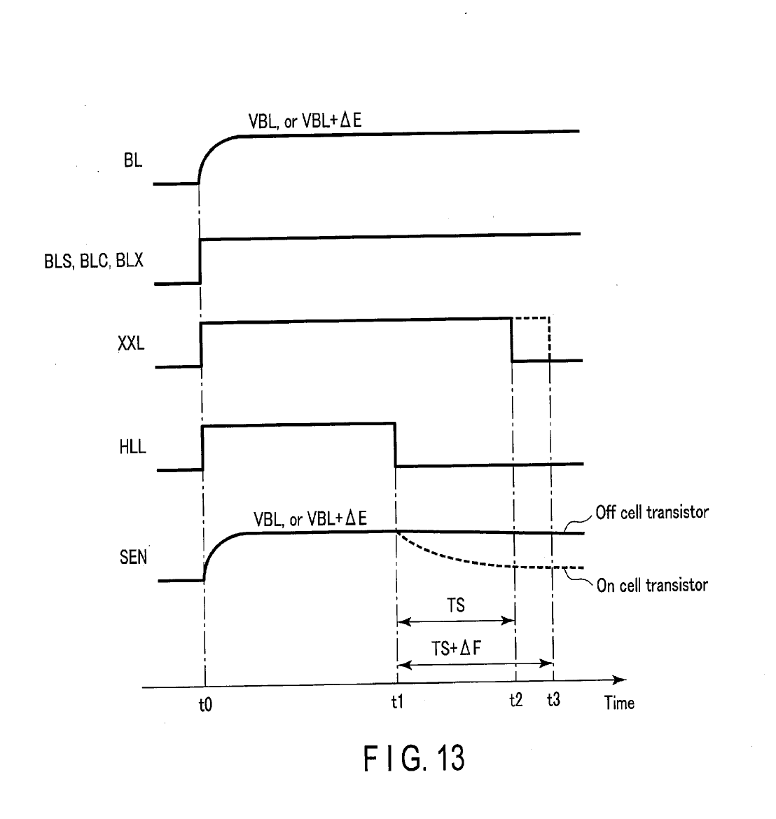

While such potentials are being applied to the bit lines BL and the unselected word lines WL, the controller 9 applies the default verification potential VVR or the adjusted verification potential VVR+ΔC to the selected word line WL. The default verification potential VVR is the potential AV for the A-level verification and is the potential VC for the C-level verification. The application of the potentials illustrated in FIG. 12 turns on, among the cell transistors MT of the write-target unit PU, those with threshold voltages lower than the potential VVR or VVR+ΔC (to be referred to as on-cell transistors hereinafter), and keeps off those with threshold voltages larger than the potential VVR or VVR+ΔC (to be referred to as off-cell transistors hereinafter). Each on-cell transistor MT forms a current path between the bit line BL coupled to the string NS which includes that on-cell transistor MT and the source line SL. A cell current flows through this current path. The presence or absence of a current path is detected by the sense amplifier circuit 3a. The detection by the sense amplifier circuit 3a is described with reference to FIG. 13.

In order to precharge the potential of the bit line BL to the potential VBL or VBL+ΔE, the potential VBL or VBL+ΔE keeps being applied to the source of the transistor QP1 by the voltage generator 8. The controller 9 then makes the signals BLS, BLC, BLX, XXL, and HLL high, and makes the potential of the node INV_S low (time t0).

The controller 9 then makes the signal HLL low to end the precharge, and then makes the state in which the potential of the bit line BL reflects the potential of the sense node SEN (time t1). Thus, a sense starts.

For a case of the sense amplifier circuit 3a being coupled to a string NS which includes an on-cell transistor MT, the potential (illustrated by the solid line) of the sense node SEN greatly falls. In contrast, for a case of the sense amplifier circuit 3a being coupled to a string NS which includes an off-cell transistor MT, the potential of the sense node SEN (illustrated by the dashed line) hardly falls.

A certain amount of time is required from the time t1 for the potential of the sense node SEN to come to a state with which on or off of the read-target cell transistor MT can be determined. Specifically, the sense ends by the transition of the signal XXL to low at the time t2 after the start of the sense at the time t1, and the time from the time t1 to the time t2 is required. This time may be the sense time TS. The controller 9 ends the sense and latches the state which is based on the potential of the sense node SEN at the time t2 after a lapse of the default sense time TS from the time t1 or at the time t3 after a lapse of the adjusted sense time TS+ΔF from the time t1.

The potential of the sense node SEN after the end of the sense reflects whether the threshold voltage of the verification-target cell transistor MT exceeds the verification potential VVR. A cell transistor MT with a threshold voltage larger than the verification potential VVR is determined to pass the write, and a cell transistor MT with a threshold voltage smaller than the verification potential VVR is determined to fail the write.

The controller 9 determines whether cell transistors MT of a particular number or ratio in the write-target unit PU pass by the first write loop. If the determination is yes, the controller determines that the write completes. If the determination is no, the controller 9 performs the second write loop.

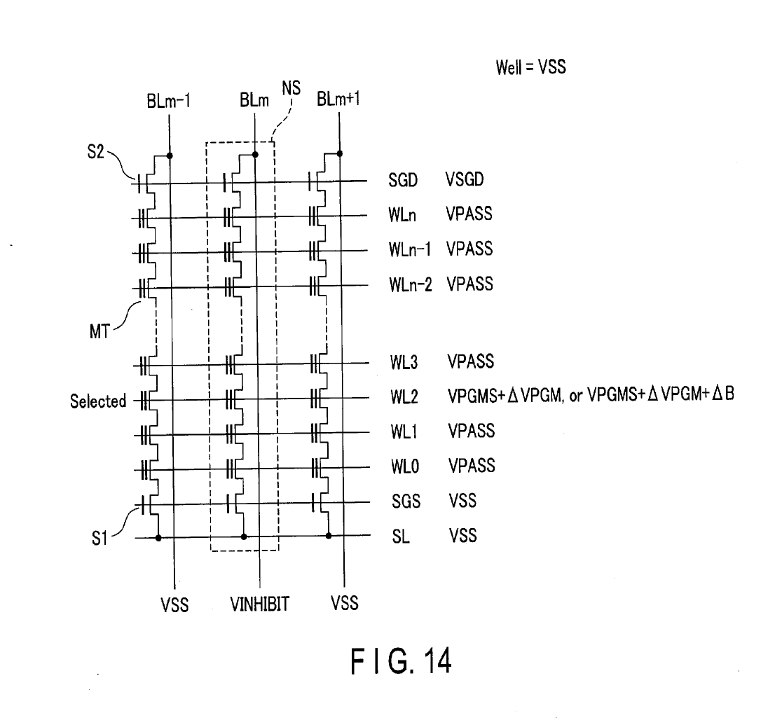

The process in the second write loop is the same as that in the first write loop only with the difference in the value of the program potential VPGM. Specifically, in the second write loop, the controller 9 uses the potential VPGMS+ΔVPGM or the potential VPGMS+ΔVPGM+ΔVB as the program potential VPGM to perform the program as illustrated in FIG. 14. In the loops after the first loop, the program voltage is not applied to the cell transistors MT which have passed the verification. To this end, the potential VINHBIT is applied to the bit lines BL coupled to the strings NS of the cell transistors MT to which the program voltage is not applied.

After the application of the program voltage ends, the controller 9 performs the verification in the second write loop. The verification is the same as the verification in the first write loop described with reference to FIGS. 12 and 13. The described write loop is repeated with the rise of the program potential in every loop until the write is determined to pass. When the write passes, the write to the upper page completes.

(Advantages)

It is known that repetition of a set of data write and erase in the cell transistors MT deteriorates the properties of the cell transistors MT. The causes of the property change include formation of defects in the tunnel insulator TI and capture of electrons by the defects. Once the electrons are captured, they are not discharged by the data erase.

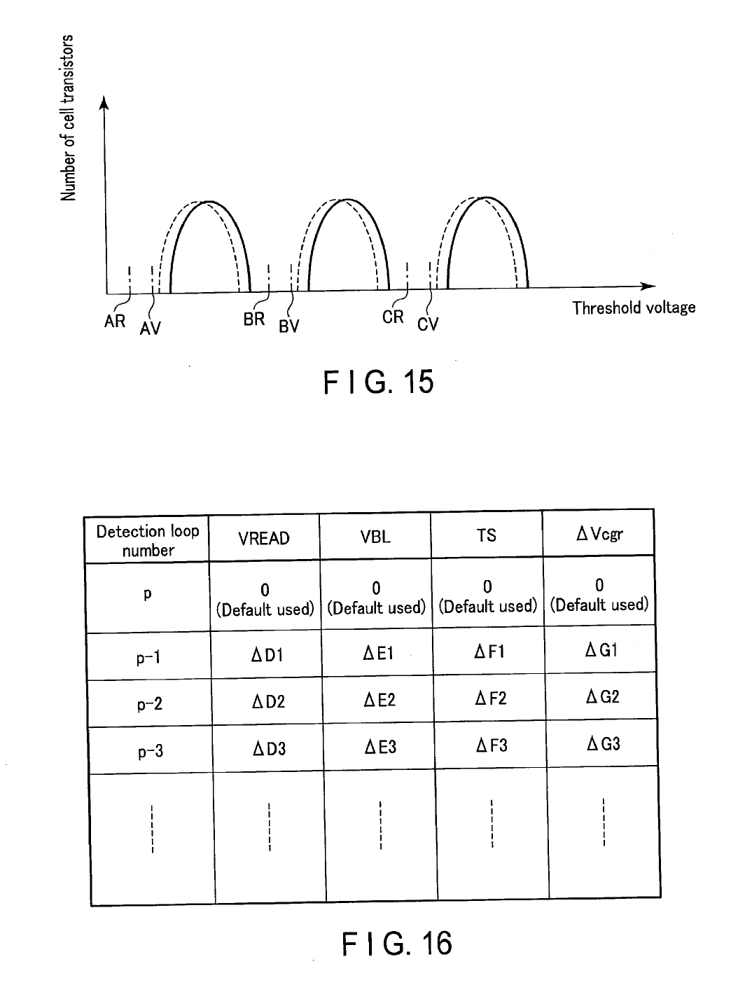

The captured electrons increase the threshold voltages of the cell transistors MT to be higher than the values before the property change. Therefore, the electron capturing shifts a distribution of threshold voltage of cell transistor MT in the positive direction, as illustrated in FIG. 15. The dashed line illustrates the distribution before the property change, and the solid line illustrates the distribution after the property change.

Cell transistors MT with threshold voltages higher than the original values can exhibit reaction to the program and verification with the parameters of the default values differently from the original reaction. For example, deteriorated cell transistors MT may come to have a target threshold voltage by fewer and/or smaller applications of program voltages. For this reason, when the deteriorated cell transistors MT are programmed with default parameters, they may have threshold voltages too high. This can cause incorrect writes or subsequent incorrect reads.

Moreover, even if the deteriorated cell transistors MT receive a particular voltage at the control gate electrode CG, they only turn on more weakly than would be without deterioration and conduct a smaller current through them. Therefore, the deteriorated cell transistors MT may not bring about correct results to the read or verification with the default parameters. In other words, the reliability of the read of the deteriorated cell transistors MT is low.

Furthermore, deterioration varies in degree, and highly deteriorated cell transistors MT hold more electrons in the defects and consequently have higher threshold voltages. For this reason, deteriorated cell transistors MT behave differently. Therefore, in a program, non-deteriorated cell transistors MT and deteriorated cell transistors MT need times of different lengths for a write.

According to the first embodiment, the memory device 1 monitors the number of times of the write loop in a lower page write, and stores the write loop number which meets a particular criterion (detection loop number). The number of times of the write loop required for the write-target cell transistors MT to come to a particular state correlates with the degree of deterioration of the cell transistors MT. More highly deteriorated cell transistors MT hold more electrons, and, therefore, have higher threshold voltages. During an upper page write, the memory device 1 reads the associated detection loop number, and uses the adjustment values determined based on the detection loop number to adjust respective one or more values of various parameters. The memory device 1 then uses the adjusted values to perform the program and verification. The parameters which may be adjusted include the start program voltage VPGMS, the increment £VPGM, the verification potential VVR, the bias potential VREAD, the precharge potential VBL, and the sense time TS.

The adjustment of the increment ΔVPGM allows the rise of the threshold voltages of cell transistors MT with easily rising threshold voltages to be adjusted finely during the programs. This enables a distribution of threshold voltages to be adjusted with high precision, and by extension can suppress incorrect reads of data that follow. This is because, for example, two adjacent distributions are suppressed from overlapping which would result in decreased accuracy in reads.

Note that, with a smaller increment ΔVPGM, the cell transistors MT need to receive more program voltages, which can increase the time for writes. However, the adjustment of increment ΔVPGM can be used along with the adjustment of the start program voltage VPGMS with the detection loop number to suppress the increase of the write time. At least, compared with a write that starts from a constant start program voltage, a large increase of time can be suppressed.

The adjustment of the verification potential VVR or bias potential VREAD turns on cell transistors MT difficult to turn on due to deterioration (or, which conduct only a small current) more strongly. The adjustment of the precharge potential VBL makes the potential difference between the bit lines BL and the source line SL larger than the default value, and causes the cell transistor MT difficult to turn on due to deterioration to conduct a larger current. The adjustment of the sense time TS can fully secure a sufficient difference between the potentials of node SEN for the case of on-cell transistors MT and the case of off-cell transistors MT even with cell currents decreased due to the deterioration. Therefore, the adjustment of the precharge potential VBL and the sense time TS enables verifications with higher accuracy, and by extension, writes of higher accuracy. The writes of higher accuracy can suppress incorrect data reads that follow. In other words, a write to the deteriorated cell transistors MT is verified correctly, and as a result data is correctly written. This suppresses reads based on erroneous writes in the first place, and suppresses incorrect reads.

### Second Embodiment

The second embodiment relates to use of the detection loop number during reads.

The memory device 10 of the second embodiment has the same functional blocks as the memory device 1 of the first embodiment (FIG. 1). The controller 9 of the memory device 10 is configured to perform the operation described in the following. The memory device 10 may include all the functions of the memory device 1 of the first embodiment.

(Operation)

When the memory device 1 receives a read command, the controller 9 starts a read from an upper or lower page specified by the command. First, the controller 9 controls components, such as the voltage generator 8, the row decoder 6, and the sense amplifier 3, to read the associated detection loop number. Specifically, the controller 9 reads the detection loop number from the read-target lower page, or reads the detection loop number from the lower page of the unit PU of the read-target upper page. The controller 9 reads data based on the read detection loop number. The operation is basically the same as the verification in the first embodiment. Specifically, the controller 9 adds adjustment values which are based on the detection loop number to the default values of parameters for read, and uses the resultant values to read the data.

The parameters among the parameters for read which may be adjusted include one or some or all of the read potential Vcgr, the bias potential VREAD, the precharge potential VBL, and the sense time TS. Additional parameters may be adjusted. The potential VREAD, the potential VBL, and the time TS are the same as those in the first embodiment. The read potential Vcgr is applied to the selected word line WL during reads as described above, and has the same function as the verification potential VVR during the verifications. The read potential Vcgr, however, differs from the verification potential VVR in the magnitude.

The controller 9 stores a table illustrated in, for example, FIG. 16, in the RAM 9a while the memory device 10 is being supplied with power. The table differs from that in the first embodiment only in types of values included therein. Specifically, the table includes adjustment values for the potential VREAD, the precharge potential VBL, and the sense time TS as in the first embodiment, and further includes adjustment values for the read potential Vcgr. The read potential Vcgr is adjusted to have a larger value for a case of a larger detection loop number. To this end, adjustment values ΔG1, ΔG2, . . . are respectively prepared for the potential Vcgr for the detection loop numbers in descending order, and all the adjustment values ΔG (ΔG1, ΔG2, . . . ) have positive values.

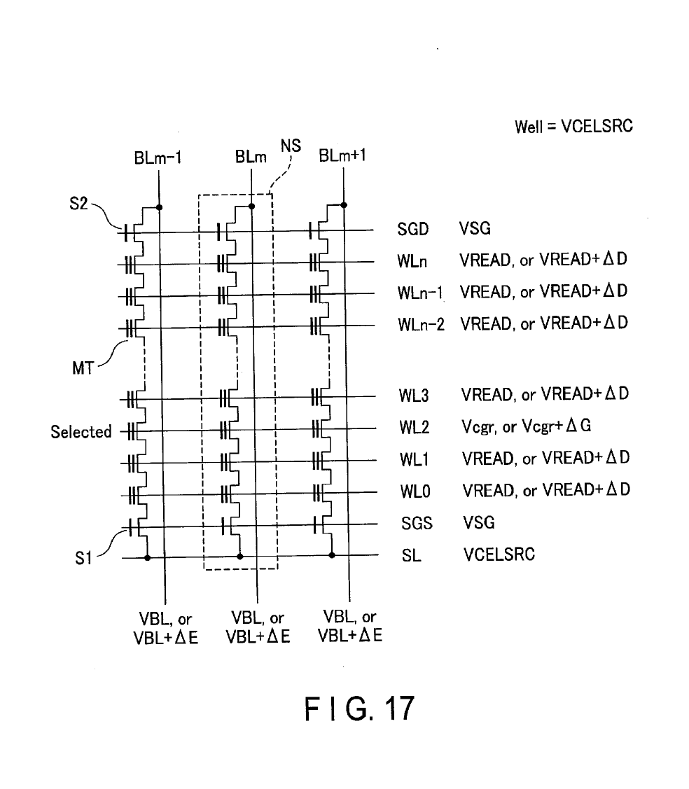

The controller 9 performs the read in the same manner as that described for the verification in the first embodiment. However, as described above and illustrated in FIG. 17, the read potential Vcgr is used instead of the verification potential VVR. Specifically, the controller 9 uses the default or adjusted parameters to perform steps which include the precharge of the bit lines BL to the potential VBL, the application of the potential VREAD to the unselected word lines, application of the potential Vcgr to the selected word line WL, and the sense with the sense time TS. The selected word line WL is applied with the default potential Vcgr or adjusted potential Vcgr+ΔG. The default read potential Vcgr is the potentials AR and CR for the read from an upper page, and the potential BR for the read from a lower page.

(Advantages)

According to the second embodiment, the memory device 10 stores the detection loop numbers, and uses values of parameters adjusted with adjustment values determined based on the detection loop numbers to perform reads. The parameters which may be adjusted include the read potential Vcgr, the bias potential VREAD, the precharge potential VBL, and the sense time TS. The adjustment of the parameters can suppress incorrect reads. The mechanism of suppression of incorrect reads through the adjustment of the read voltage Vcgr is the same as that through the adjustment of the verification potential described in the first embodiment.

<Others>

The description so far is based on storing of two-bit data per cell transistor MT. The embodiments are not limited to this storing method; but are applicable to storing of data of three or more bits in one cell transistor MT. For example, the detection loop number is found during a write to the first page in a particular unit PU, and the detection loop number is written in the first page. The detection loop number is then referred to during a write to the second or higher page or during a read from a page in that unit PU.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A memory device comprising:
cell transistors; and
a controller which
is configured to write data in a first page and a second page and read data from the first and second pages, and
when the controller writes data in the second page of the cell transistors with data written in the first page, reads data from the first page, uses a first value or a second value for a first parameter based on the read data, and uses a third value or a fourth value for a second parameter based on the read data.

2. The device of claim 1, wherein
the cell transistors comprise respective control gate electrodes coupled to a word line,
each of the first and second parameters is one of:
a first voltage first applied to the word line during the write to the second page,
a difference of two voltages applied to the word line,
a second voltage applied to a bit line electrically coupled to one of the cell transistors,
a third voltage applied to a second word line different from the word line,
a fourth voltage applied to the word line and being smaller than the third voltage, and
a time taken for sensing a potential of a node coupled to the bit line.

3. The device of claim 2, wherein
the third and fourth voltages are applied while the second voltage is being applied to the bit line.

4. The device of claim 3, wherein
the write to the second page includes a repetition of a loop which includes a first section and a second section, and
the first voltage is applied to the word line in the first section of a first loop,
the difference of two voltages is a difference between a voltage applied to the word line in the first section of a loop and a voltage applied to the word line in the first section of the next loop, and
the second voltage is applied to the bit line in the second section, and
the sense is performed in the second section.

5. The device of claim 4, wherein
when the first parameter is one of the first voltage, the second voltage, the third voltage, the fourth voltage, and the time, the second value is larger than the first value, and
when the first parameter is the difference, the second value is smaller than the first value.

6. The device of claim 5, wherein
the controller
applies different voltages two or more times to the word line during the write to the first page, and
writes a number of times of application of the voltages with which the cell transistors come to fulfill a condition.

7. The device of claim 6, wherein
the controller uses the first or second value for the first parameter and the third or fourth value for the second parameter based on the number.

8. A memory device comprising:
cell transistors; and
a controller which
is configured to write data in a first page and a second page and read data from the first and second pages,
when the controller reads data from the cell transistors, reads data from the first page and uses a first value or a second value for a first parameter based on the read data.

9. The device of claim 8, wherein
the cell transistors comprise respective control gate electrodes coupled to a word line,
the first parameter is one of:
a first voltage applied to a bit line electrically coupled to one of the cell transistors,
a second voltage applied to a second word line different from the word line,
a third voltage applied to the word line and being smaller than the second voltage, and
a time taken for sensing a potential of a node coupled to the bit line.

10. The device of claim 9, wherein
the second value is larger than the first value.

11. The device of claim 10, wherein
the controller
applies different voltages two or more times to the word line during the write to the first page, and
writes a number of times of application of the voltages with which the cell transistors come to fulfill a condition.

12. The device of claim 11, wherein
the controller uses the first or second value for the first parameter.

13. A memory device comprising:
cell transistors comprising respective control gate electrodes coupled to a word line; and
a controller which
is configured to write data in a first page and a second page and read data from the first and second pages,
when the controller writes data in the second page of the cell transistors with data written in the first page, reads data from the first page and uses a first value or a second value for a parameter other than a voltage first applied to the word line in the write to the second page based on the read data.

14. The device of claim 13, wherein
the first parameters is one of:
a difference of two voltages applied to the word line,
a first voltage applied to a bit line electrically coupled to one of the cell transistors,
a second voltage applied to a second word line different from the word line,
a third voltage applied to the word line and being smaller than the second voltage, and
a time taken for sensing a potential of a node coupled to the bit line.

15. The device of claim 14, wherein
the third and fourth voltages are applied while the second voltage is being applied to the bit line.

16. The device of claim 15, wherein
the write to the second page includes a repetition of a loop which includes a first section and a second section, and
the first voltage is applied to the word line in the first section of a first loop,
the difference of two voltages is a difference between a voltage applied to the word line in the first section of a loop and a voltage applied to the word line in the first section of the next loop, and
the second voltage is applied to the bit line in the second section, and
the sense is performed in the second section.

17. The device of claim 16, wherein
when the parameter is one of the first voltage, the second voltage, the third voltage, and the time, the second value is larger than the first value, and
when the parameter is the difference, the second value is smaller than the first value.

18. The device of claim 17, wherein
the controller
applies different voltages two or more times to the word line during the write to the first page, and
writes a number of times of application of the voltages with which the cell transistors come to fulfill a condition.

19. The device of claim 18, wherein
the controller uses the first or second value for the parameter based on the number.
